(19) United States
(12) Patent Application Publication
(10) Pub. No.: US 2006/0273815 A1
(43) Pub. Date: Dec. 7, 2006

(54) Substrate support with integrated prober drive

(75) Inventors: Benjamin M. Johnston, Los Gatos, CA (US); Fayez E. Abboud, Pleasanton, CA (US); Hung T. Nguyen, Fremont, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/298,648

(22) Filed: Dec. 8, 2005

Related U.S. Application Data
(60) Provisional application No. 60/688,168, filed on Jun. 6, 2005.

(51) Int. Cl. G01R 31/26

(52) U.S. Cl. 324/765

(57) ABSTRACT

A method and apparatus for testing a plurality of electronic devices on a large area substrate is described. The apparatus includes a prober positioning assembly coupled to a substrate support within a testing chamber. The substrate support is a testing table capable of movement in X, Y and Z axes and the prober positioning assembly is capable of movement relative to the testing table. A prober exchanger is positioned adjacent the testing chamber and facilitates prober transfer through cooperative and relative movement with the prober positioning assembly. A load lock chamber having a single transfer door actuator, an atmospheric substrate lift, and a plurality of substrate alignment members is also described.

### CROSS-REFERENCE TO RELATED APPLICATIONS

This application claims benefit of U.S. Provisional Patent application Ser. No. 60/688,168, filed Jun. 6, 2005, which is incorporated herein by reference.

### BACKGROUND OF THE INVENTION

1. Field of the Invention

Embodiments of the present invention generally relate to testing electronic devices on large area substrates. More particularly, the invention relates to a test system for electron beam testing of electronic devices on large area substrates.

2. Description of the Related Art

Flat panel displays have recently become commonplace in the world as a replacement for the cathode ray tubes (CRT's) of the past. The displays have many applications in computer monitors, cell phones and televisions to name but a few. The LCD has several advantages over the CRT, including higher picture quality, lighter weight, lower voltage requirements, and low power consumption.

One type of flat panel display includes a liquid crystal material sandwiched between two panels made of glass, a polymer material, or other suitable material capable of having electronic devices formed thereon. One of the panels may include a thin film transistor (TFT) array while the other panel may include a coating that functions as a color filter. The two panels are suitably joined to form a large area substrate having one or more flat panel displays located thereon.

A part of the manufacturing process requires testing of the large area substrate to determine the operability of each pixel in the display or displays located on the large area substrate. Electron beam testing (EBT) is one procedure used to monitor and troubleshoot defects during the manufacturing process. In a typical EBT process, TFT response within a pixel electrode area is monitored to provide defect information by applying certain voltages to the TFT's while an electron beam is directed to an area of the large area substrate under investigation. Secondary electrons emitted from the area under investigation are monitored to determine the TFT voltages.

The demand for larger displays, increased production and lower manufacturing costs has created a need for new testing systems that can accommodate larger substrate sizes while increasing throughput time. Current large area display processing equipment generally accommodates substrates up to about 2200 mm×2400 mm and larger. The size of the processing equipment as well as the process throughput time is a great concern to flat panel display manufacturers, both from a financial standpoint and a design standpoint.

Therefore, there is a need for a test system to perform electron beam testing on large area substrates that minimizes clean room space and reduces testing time.

### SUMMARY OF THE INVENTION

Embodiments of the present invention generally includes a test system and process for testing electronic devices on large area substrates using an electronic test device such as a prober. In one embodiment, a prober is provided which includes a rectangular frame that has substantially the same area as a large area substrate. The frame may have one or more prober bars coupled to the frame having contact pins on a lower surface to contact conductive contact areas located on the large area substrate. In another embodiment, the frame does not have prober bars and the contact pins are disposed on a lower surface of the frame to contact conductive contact areas located on the large area substrate. The frame has appropriate electrical connections to the contact pins and a mating electrical connection to a portion of the testing table. The frame also has an extended member on two opposing sides to facilitate transfer of the prober into and out of a testing chamber. The frame includes one or more alignment members coupled to the frame to facilitate alignment of and provide stability to the prober when the prober is positioned in the testing chamber.

In another embodiment, a test system is provided which includes a prober positioning assembly coupled to a substrate support, such as a testing table, within a testing chamber. The testing chamber is selectively opened to ambient environment and may be sealed from ambient environment and pumped down to a suitable pressure by one or more vacuum pumps coupled to the testing chamber. The testing table is made of three individual stages that are adapted to move independently in the X, Y, and Z directions, wherein a large area substrate is supported on the uppermost stage. The prober positioning assembly is adapted to facilitate transfer and support of one or more probers above the testing table, and the prober positioning assembly is configured to move independent of the testing table. The prober positioning assembly includes at least two lift members having a plurality of friction reducing members thereon and the lift members are adapted to move in at least a vertical direction by actuation of at least two lift motors. The lift motors are coupled on one end to the lift members and to the testing table on the other end. The testing chamber may be coupled to a load lock chamber or, alternatively, the testing chamber may function as a load lock chamber. The testing chamber may be adapted to store one or more probers on a lower surface thereof. Alternatively, or additionally, the load lock chamber may be adapted to store one or more probers above the load lock chamber. The testing chamber further includes a plurality of electron beam columns coupled to an upper surface of the testing chamber and are adapted to perform a testing sequence on one or more large area substrates.

A prober exchanger may be coupled to or otherwise positioned adjacent the testing chamber and is adapted to store, support, and facilitate transfer of one or more probers into and out of the testing chamber through a movable process wall coupled to the testing chamber. The prober exchanger has at least one support member that is movably attached to a frame and configured to facilitate support, transfer, and storage of one of the one or more probers. The at least one support member is adapted to move in at least a vertical direction relative the frame by at least one actuator coupled between the frame and the support member. The at least one support member may have a friction reducing surface to enhance transfer of the one or more probers.

In another embodiment, a prober transfer assembly includes a lift member configured to move in at least a vertical direction by at least one actuator. The at least one actuator is coupled to the lift member and a testing table within a testing chamber. The lift member may move in a vertical direction relative the testing table by action of the at least one actuator. The lift member may include a channel formed in an upper surface of the lift member and the channel may include a plurality of friction reducing members disposed in the channel to assist in transfer of one or more probers by movably supporting the probers during transfer. The lift member coupled to the testing table is moved in a horizontal direction to a prober transfer position by action of the testing table. The prober transfer position of the lift member coincides with a prober transfer position of a support member outside the chamber, whereby the lift member and the support member are in substantially the same horizontal and vertical plane to facilitate transfer of one or more probers from the lift member to the support member, or vice versa, in a horizontal motion.

In another embodiment, a test system is described having two load lock chambers and two testing chambers with a prober exchanger positioned therebetween. The prober exchanger is adapted to provide support for and facilitate transfer of one or more probers between the two testing chambers. The two testing chambers each have a prober positioning assembly coupled to a testing table within the testing chamber. The prober exchanger includes a plurality of support members disposed on a frame adjacent the testing chamber.

In another embodiment, a load lock chamber is described having a dual slot substrate support coupled to two externally mounted drives adapted to move the dual slot substrate support in at least a vertical direction. The load lock chamber has a transfer door that is selectively opened and closed to ambient environment by one actuator. The transfer door is adapted to facilitate transfer of one or more large area substrates to and from ambient environment by selectively opening to allow an atmospheric substrate exchange. The load lock chamber further includes a plurality of substrate alignment members adapted to alter the orientation of a substrate supported by at least two support trays of the dual slot substrate support. The load lock chamber, in one embodiment, is adapted to couple to a testing chamber capable of testing electronic devices on a large area substrate.

In another embodiment, a method for transferring one or more probers into and out of a testing chamber is described. The method includes moving a support member adjacent the testing chamber to a first vertical position, moving a testing table within the chamber into alignment with the support member, and transferring a prober into or out of the testing chamber in a lateral direction. The method may further include moving the transfer assembly coupled to the testing table to substantially match the vertical position of the support member before transferring the prober, and moving the support member to a second vertical position and transferring the prober from the transfer assembly to the support member.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an isometric view of one embodiment of an exemplary electron beam test system.

FIG. 2 is an isometric view of another embodiment of an exemplary electron beam test system having two testing chambers.

FIG. 3 is an isometric view of one embodiment of a prober exchanger.

FIG. 4 is a partial side view of an exemplary electron beam test system.

FIG. 5 is a partial isometric view of a typical prober.

FIG. 6 is a perspective view of a prober adjacent a testing table in a prober transfer position.

FIG. 7A is an exploded isometric view of a portion of the testing table of FIG. 6.

FIG. 7B is a partial side view of the prober exchanger positioned adjacent the testing chamber.

FIG. 8 is a flow chart showing steps of an exemplary operational sequence.

FIG. 9 shows another embodiment of an exemplary electron beam test system.

FIG. 10 is an isometric view of one embodiment of a load lock chamber.

FIG. 11 is a schematic side view of a portion of the load lock chamber.

### DETAILED DESCRIPTION

Embodiments of the present invention include an apparatus and method for performing a testing process on large area substrates. An exemplary testing system will be described using electron beam testing (EBT), although other test systems may be used. The large area substrates as used herein are made of glass, a polymeric material, or any other suitable substrate material capable of having electronic devices formed thereon.

Embodiments depicted in this application will refer to various drives, motors and actuators that may be one or a combination of the following: a pneumatic cylinder, a hydraulic cylinder, a magnetic drive, a stepper or servo motor, a screw type actuator, or other type of motion device that provides vertical movement, horizontal movement, or combinations thereof. A prober as used herein is any device that may be used to test electronic devices on a substrate.

Various components described herein may be capable of independent movement in horizontal and vertical planes. Vertical is defined as movement orthogonal to a horizontal plane and will be referred to as Z direction. Horizontal is defined as movement orthogonal to a vertical plane and will be referred to as X or Y direction, the X direction being movement orthogonal to the Y direction, and vice-versa. The X, Y, and Z directions will be further defined with directional insets included, as needed, in the Figures to aid the reader.

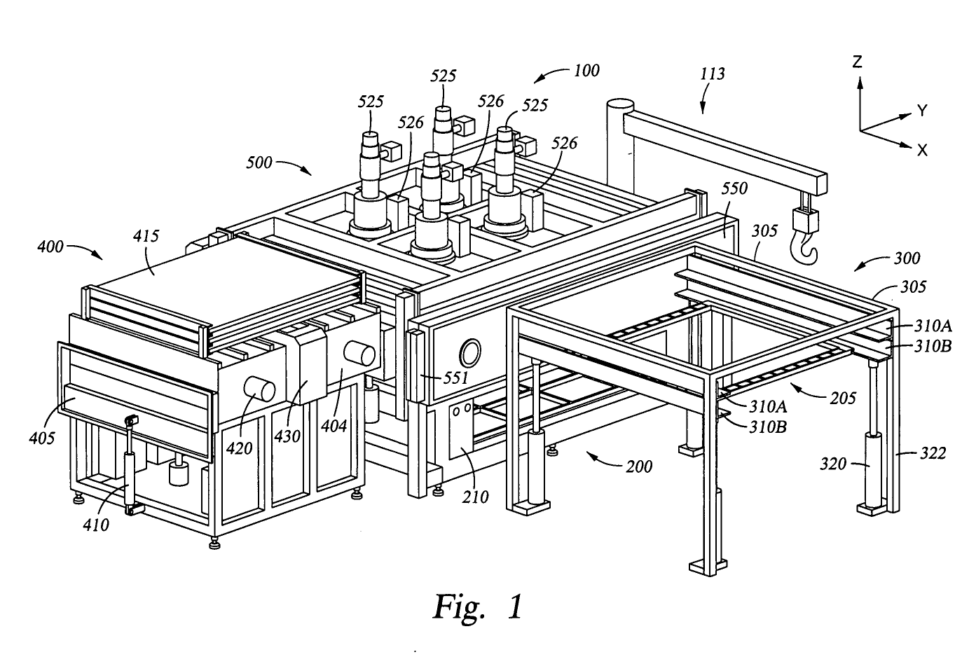

FIG. 1 is an isometric view of an exemplary electron beam test (EBT) system 100 configured to test electronic devices on large area substrates up to and exceeding 2200 mm×2400 mm. The EBT system 100 includes a testing chamber 500, a load lock chamber 400, a prober exchanger 300, and a crane assembly 113. The testing chamber 500 includes four electron beam columns 525 that are adapted to direct an electron beam toward a large area substrate under test and detect secondary electrons emitted from the substrate. The testing chamber 500 also includes four microscopes 526 adapted to inspect areas of interest on the large area substrate. While four electron beam columns 525 and four microscopes 526 are shown, the testing chamber 500 is not limited to this configuration and any number of electron beam columns 525 and microscopes 526 may be used.

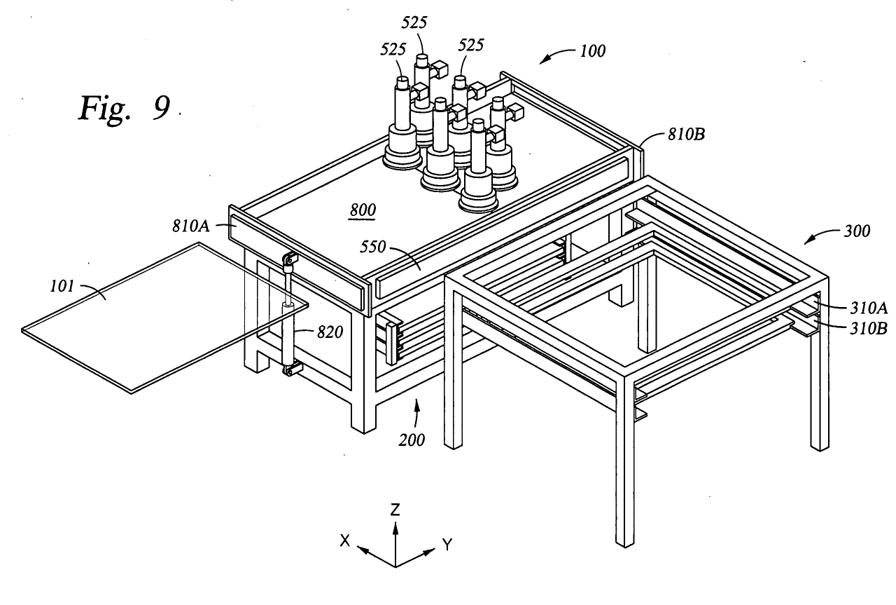

The load lock chamber 400 has a transfer door 405 that is selectively opened and closed by a door actuator 410. The transfer door 405 facilitates transfer of one or more large area substrates into and out of the load lock chamber 400 by allowing access to the interior of the load lock chamber when the transfer door 405 is opened. The load lock chamber 400 is adapted to be positioned adjacent a substrate queuing device which may be an atmospheric robot, a conveyor system, or any device adapted to transfer a large area substrate between ambient environment and the load lock chamber 400. The load lock chamber may include a pump system adapted to provide negative pressure to the load lock chamber 400. The load lock chamber 400 also includes a plurality of substrate aligners 420 and an atmospheric lift actuator 430 coupled to the load lock chamber body 404, both of which will be described in reference to FIG. 9.

The EBT system 100 includes a prober storage area 200 which houses one or more probers 205 on a lower surface of the testing chamber 500. The prober storage area 200 is shown under the testing chamber 500 coupled to the testing chamber frame and may be sealed by a door 210 that protects the one or more probers 205. An extra prober storage location 415 may be disposed on an upper portion of the load lock chamber 400 coupled to the chamber body 404. The crane assembly 113 may be employed to facilitate transfer of a prober between the storage location 415, the storage area 200, and the prober exchanger 300. The crane assembly 113 may also facilitate transfer of probers from other locations adjacent the EBT system 100.

The prober exchanger 300 is a modular unit disposed adjacent a prober door 550 coupled to the testing chamber 500. The prober exchanger 300 facilitates transfer of one or more probers 205 into and out of the testing chamber 500 through a prober door 550. The prober door 550 is selectively opened to ambient environment to allow prober transfer to occur between the testing chamber 500 and the prober exchanger 300. The prober door 550 is shown in a closed position, thereby effectively sealing the interior volume of the testing chamber 500 from ambient environment and allowing the interior volume to be pumped down to a suitable pressure for testing by a vacuum system coupled to the testing chamber 500. The prober door 550 is selectively opened and closed by the action of two door actuators 551 coupled to the prober door 550 and the frame of the testing chamber 500.

The prober exchanger 300 has an upper support member 310A and a lower support member 310B movably coupled to a frame 305. Each of the support members 310A, 310B are adapted to receive and support one prober 205. The upper support member 310A and the lower support member 310B are coupled to at least one support member actuator 320 that may be mounted on a lower surface of the support members 310A, 310B to the frame 305. The support member actuators 320 are adapted to provide at least vertical movement to the support members 310A, 310B configured to position the support members and facilitate transfer of the one or more probers 205 into and out of the testing chamber 500. While one upper support member 310A and one lower support member 310B is shown, the prober exchanger 300 is not limited to this configuration and any number of support members 310A, 310B may be used. By providing more support members on the prober exchanger 300 to support more probers for subsequent transfer into the testing chamber 500, the prober exchanger 300 may also be used for prober storage as well as a transfer mechanism. While four support member actuators 320 are shown coupled to the frame 305, the prober exchanger 300 is not limited to this configuration and may have any number of support member actuators 320.

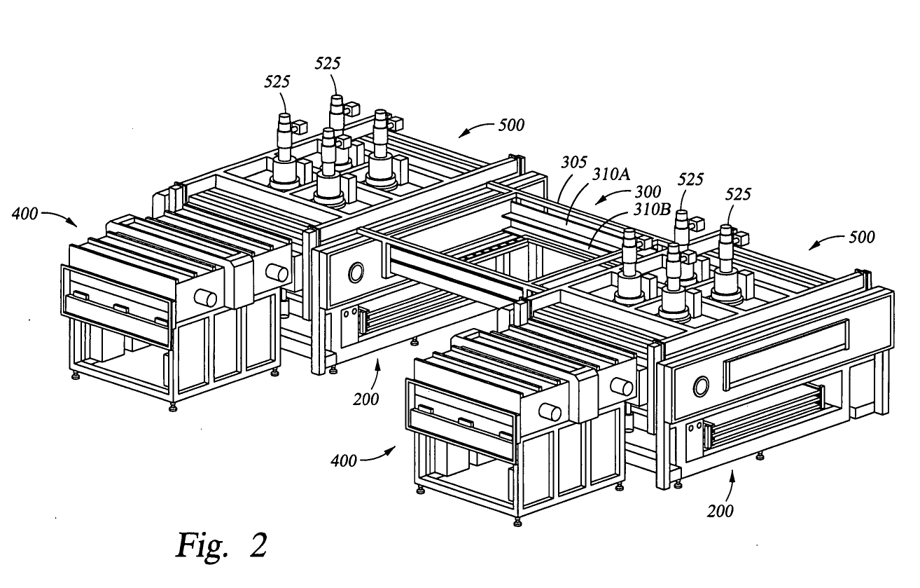

FIG. 2 is another embodiment of an exemplary EBT system 100 having two load lock chambers 400, two testing chambers 500, and a prober exchanger 300 therebetween. This embodiment is the same as the embodiment shown in FIG. 1 except the prober exchanger 300 has a frame 305 that is coupled to two testing chambers 500. The prober exchanger 300 may facilitate transfer of one or more probers 205 into and out of the testing chambers 500 from this central location. The EBT system 100 may also include a crane 113 to facilitate transfer of one or more probers from various storage locations adjacent the testing chambers 500 (not shown in this view).

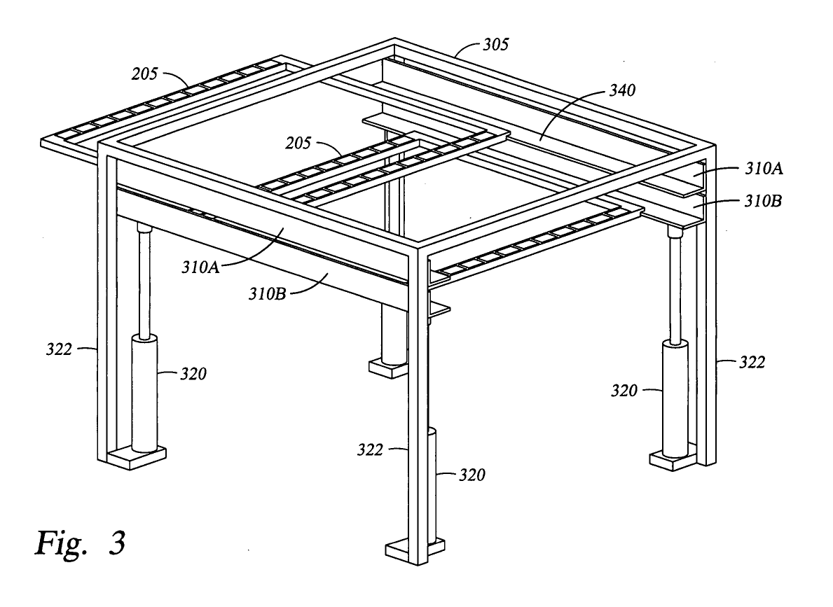

FIG. 3 is an isometric view of one embodiment of a prober exchanger 300. The prober exchanger 300 has at least one upper support member 310A and at least one lower support member 310B movably coupled to a frame 305. Four support member lifts 320 are adjacent a vertical portion 322 of the frame 305 and are adapted to provide at least vertical movement to the support members 310A, 310B relative the frame 305. Each of the support members 310A, 310B in this embodiment are L shaped brackets that are suitably joined together so that any movement provided by the support member lifts 320 causes both of the support members 310A, 310B to move. When the support members 310A, 310B are joined, one or both of the support members 310A, 310B may be coupled to the vertical portion 322 in a manner that allows at least vertical movement to the support members relative the vertical portion 322. The prober exchanger is adapted to support, facilitate transfer of, and provide temporary storage for at least one prober 205. A prober 205 is shown at least partially within and supported by the upper support member 310A and another prober 205 is shown within the support member 310B.

The probers 205 in this embodiment are configured to move relative the frame 305 and support members 310A, 310B and the frame 305 is configured to remain stationary. The support members 310A, 310B adapted to move in a vertical direction only in this embodiment. The support members 310A, 310B may have a friction reducing surface 340 that minimizes friction between the prober frame 305 and the support members 310A, 310B. In one embodiment, the friction reducing surface 340 may comprise a plurality of rollers adapted to minimize friction during transfer of the prober frame 305. In another embodiment, the friction reducing surface 340 may include a coating, such as a Teflon® material adapted to support the prober frame 305 and minimize friction during movement. In operation, one of the support members 310A, 310B is aligned by the support member actuators 320 to a prober transfer position. Once the support members are aligned, the prober 205 is moved out of the respective support member into the testing chamber or into the respective support member from the testing chamber. The prober exchanger 300 may have one or more support members 310A, 310B that are not pre-loaded at any point in time in order to receive a prober from the testing chamber.

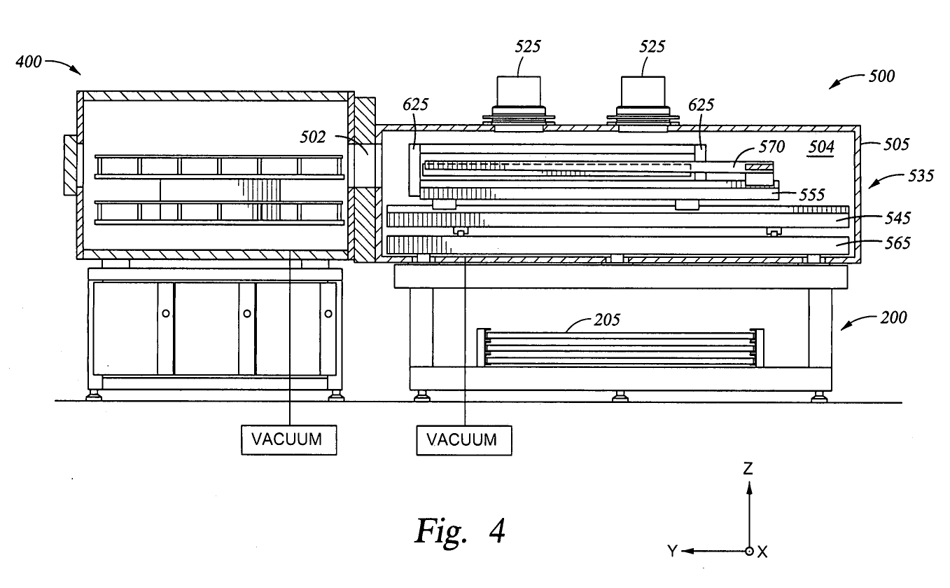

FIG. 4 is a partial side view of an exemplary EBT test system 100 as shown in FIG. 1. The EBT test system 100 has a load lock chamber 400 coupled to a testing chamber 500 by a slit valve 502 adapted to selectively isolate an interior volume 504 of the testing chamber 500 from the environment of the load lock chamber 400. The interior volume 504 is surrounded by a housing 505 and is selectively isolated from ambient environment by the prober door 550 (shown in FIG. 1). The interior volume 504 includes a testing table 535 made of three stages that are adapted to move in X, Y and Z directions. A large area substrate (not shown) enters and exits through the slit valve 502 from the load lock chamber 400 and is supported by an upper stage of the testing table 535 during testing. During this testing, the substrate, supported by the testing table 535, may move in at least the X direction, the Y direction, and the Z direction under the electron beam columns 525.

The testing table 535 is coupled to a base 565. A lower stage 545 is movably coupled to the base 565 and the lower stage moves linearly across an upper surface of the base in a Y direction. An upper stage 555 is movably coupled to the lower stage 545 and moves linearly across an upper surface of the lower stage 545 in an X direction. A Z stage 536 is movably coupled to the upper stage 555 and moves linearly in a Z direction by the action of a plurality of drives (not shown) coupled between the upper surface of the upper stage 555 and a lower surface of the Z stage 536. An end effector 570 (shown in phantom) is coupled to the upper stage 555 and is adapted to move horizontally in the Y direction to transfer a substrate to and from the load lock chamber 400. The end effector 570 comprises a plurality of fingers adapted to support the substrate. The Z stage 536 is configured to have slots adapted to receive the fingers of the end effector 570. The fingers are sized not to interfere with the operation of the Z stage 536 allowing the Z stage to raise or lower relative the fingers of the end effector 570. Details of a suitable testing table and methods of transferring a substrate into and out of the testing chamber using an end effector may be found in commonly assigned U.S. Pat. No. 6,833,717, entitled “Electron Beam Test System with Integrated Substrate Transfer Module,” which issued Dec. 21, 2004, and co-pending U.S. Provisional Patent Application Ser. No. 60/592,668, entitled “Electron Beam Test System Stage,” filed Jul. 30, 2004, both disclosures of which are herein incorporated by reference to the extent they are consistent with this disclosure.

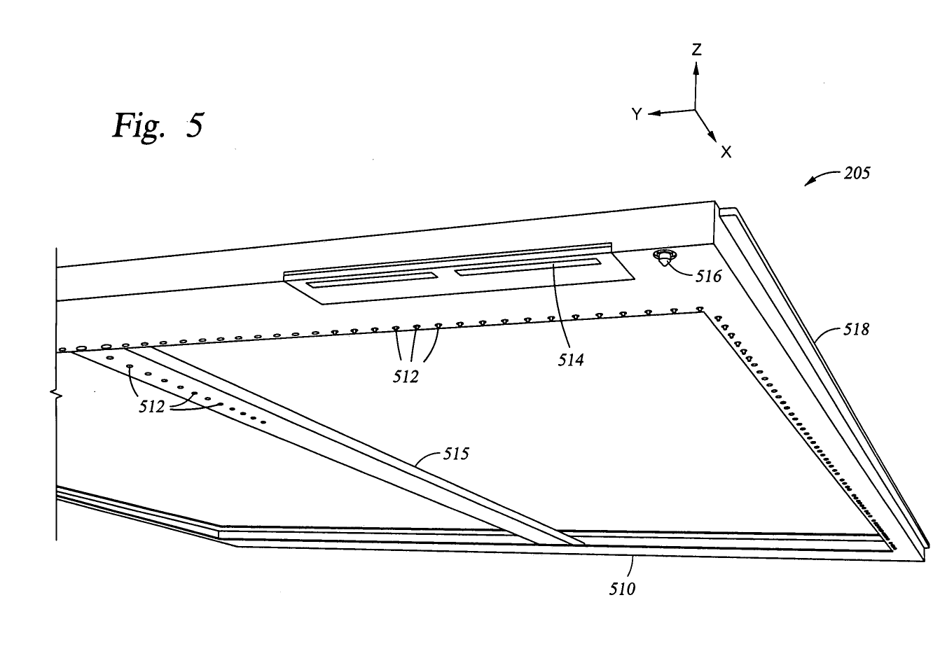

FIG. 5 is a partial isometric view of an exemplary prober 205. The prober 205 includes a rectangular prober frame 510 with at least one alignment member 516 that facilitates alignment of the prober frame 510 and provides stability when the prober 205 is coupled to the testing table. In this embodiment, the prober frame has two alignment members 516 on opposing corners of the prober frame 510 (only one is seen in this view). The two alignment members 516 in this embodiment are a tapered pin coupled to the prober frame 510. In other embodiments, the alignment members 516 may each be a hole adapted to receive a pin that is coupled to the testing table. In another embodiment, each of the alignment members 516 may be a pin coupled to a spring to allow the pin to move relative the prober frame 510.

In this embodiment, the prober frame 510 includes a plurality of contact holes disposed on a lower surface of the frame 510 adapted to receive one or more prober bars 515 coupled to the prober frame 510 on opposing sides. The prober bars 515 have a plurality of contact pins 512 disposed on a lower surface of the prober bar 515 adapted to contact various conductive contact areas on a large area substrate. In order to contact the conductive contact areas on the substrate, the surface area of the prober frame 510 typically exceeds the surface area of the large area substrate. The prober frame 510 is generally proportioned in length and width to equal or exceed the length and width of the large area substrate. In other embodiments, the prober frame 510 may include the contact pins 512 that are configured to contact various electrically conductive areas on the large area substrate. The prober frame 510, or the prober bars 515, that may be attached to the prober frame are configured to include contact pins 512 that are arranged to match a specific display configuration on the large area substrate. The contact pins 512 are in communication with at least one electrical contact block 514 that mates with a corresponding contact block connection coupled to the testing table (not shown in this view). The contact block connection is coupled to a controller typically located outside the testing chamber. When the contact pins 512 of the prober 205 are brought into contact with the conductive contact areas, an electrical signal provided by the controller communicates the electrical signal to the conductive areas and various electronic devices on the large area substrate. Thus, the pixels formed on the large area substrate may be energized for a testing sequence. Examples of probers that may be adapted to benefit from the invention are disclosed in U.S. Patent Publication No. 2004/0145383, entitled “Apparatus and Method for Contacting of Test Objects,” filed Nov. 18, 2003, which is incorporated herein by reference to the extent it is not inconsistent with this disclosure. Other probers that may be used are disclosed in U.S. patent application Ser. No. 10/889,695, entitled “Configurable Prober for TFT LCD Array Testing,” filed Jul. 12, 2004, and U.S. patent application Ser. No. 10/903,216, entitled “Configurable Prober for TFT LCD Array Test,” filed Jul. 30, 2004, both applications of which are incorporated by reference herein to the extent the applications are not inconsistent with this disclosure.

The prober 205 also has an extended member on at least two opposing sides of the prober frame 510. In one embodiment, the extended member 518 is a laterally protruding bracket aligned with the X direction. Another extended member 518 (not shown in this view) laterally protrudes along the opposing portion of the frame 510 on the other side of the prober 205. The extended members 518 facilitate transfer and support of the prober 205.

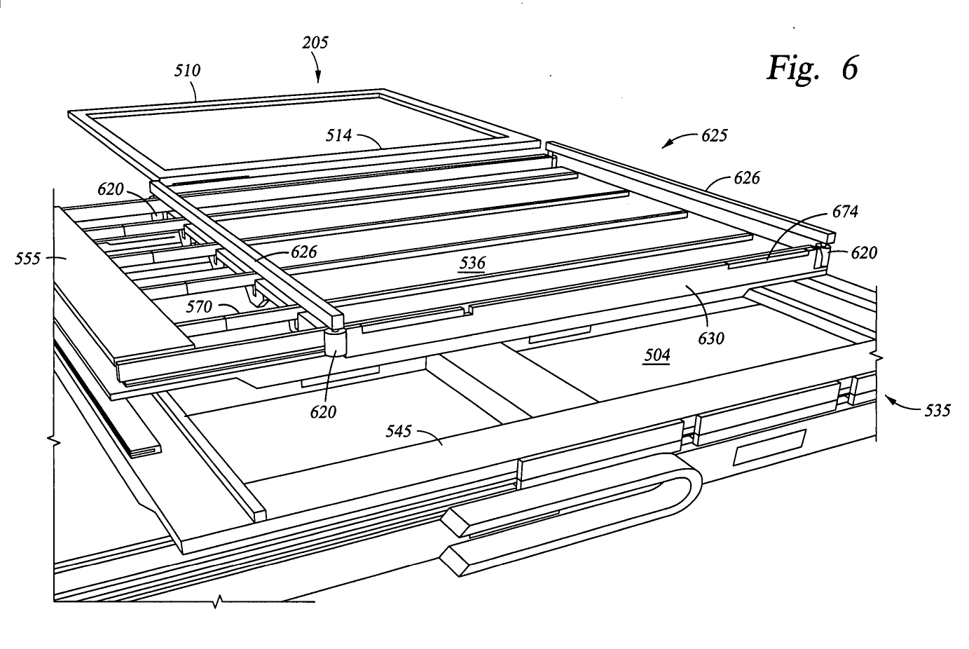

FIG. 6 is a perspective view of the prober 205 adjacent a testing table 535. The prober 205 is shown adjacent the testing table 535 aligned with a prober positioning assembly 625 coupled to the testing table 535. The prober may be in this position as transferring into or out of the interior volume 504 of the testing chamber 500, the body of the testing chamber not shown in this view for ease of description. Also not shown in this view for clarity, the prober 205 would be supported and aligned vertically by one of the support members 310A, 310B of the prober exchanger 300 and the testing table 535 may move in the X and/or Y direction to arrive at the prober transfer position.

The prober positioning assembly 625 includes two prober lift members 626 disposed on opposing sides of the testing table 535. The prober lift members 626 are coupled to a plurality of Z-motors 620 at each corner of the testing table 535. It is contemplated that each of the prober lift members 626 may by raised and lowered by motors in other locations disposed on the testing table 535. Alternatively, each of the prober positioning assemblies 625 may employ only one Z drive coupled to the testing table 535. In this embodiment, the Z-drives 620 are coupled to the testing table 535 adjacent a prober support 630. The prober support 630 is coupled to the testing table 535 on opposing sides and is adapted to provide support for a prober 205 above the upper stage 536 as well as provide a mounting point for the plurality of Z-motors 620. The prober support 630 also provides an interface for the electrical connection blocks 514 of the prober 205 via a contact block connection 674 that is appropriately connected to a controller (not shown).

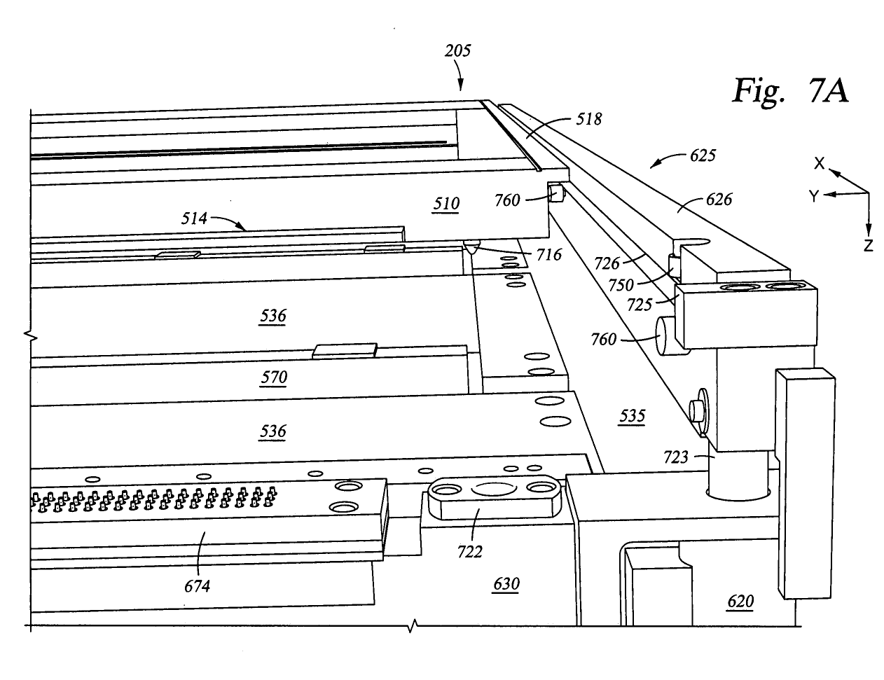

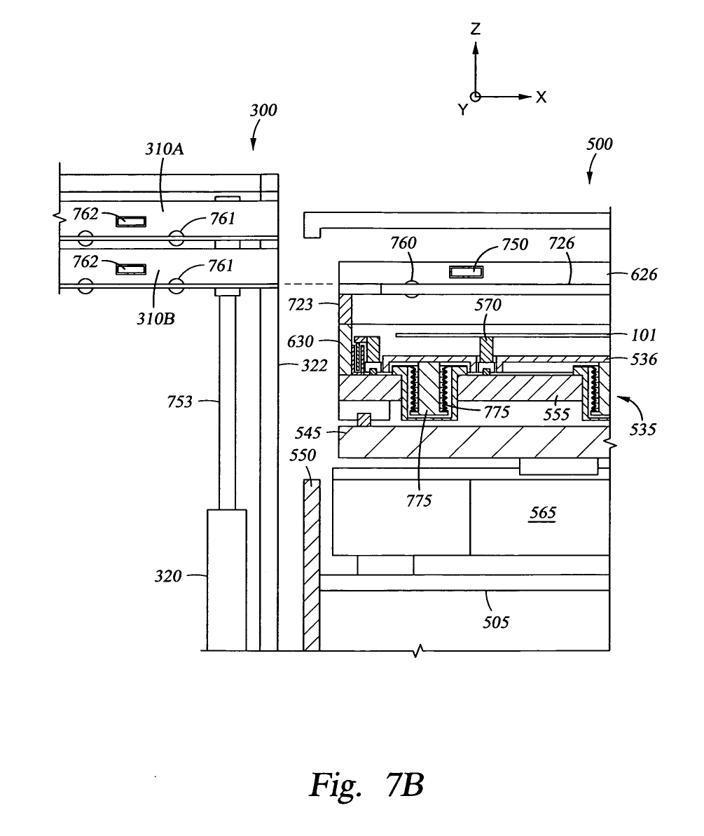

FIG. 7A is an exploded isometric view of a portion of the testing table 535. The prober 205 is shown in a transfer position above the Z stage 536. One side of the prober positioning assembly 625 is shown having a plurality of friction reducing members coupled to the prober lift member 626. The friction reducing members are adapted to facilitate transfer of the prober 205 by movably supporting the extended member 518 of the prober frame 510. In this embodiment, the prober lift member includes a channel 726 adapted to receive the extended member 518 of the prober frame 510. The plurality of friction reducing members in this embodiment are upper roller bearings 750 and lower roller bearings 760 coupled to the prober lift member 626 adjacent the channel 726. The lower roller bearings 760 support the extended member 518 and the upper roller bearings 750 act as a guide for the extended member 518 during transfer of the prober frame 510. Also shown is a locating member 716 integral to the prober 205 adapted to seat in a corresponding receptacle 722 integral to the prober support 630 in order to facilitate alignment and support of the prober 205 when positioned on the prober support 630.

FIG. 7B is a partial side view of the prober exchanger 300 positioned adjacent the testing chamber 500. The testing table 535 is shown in a prober transfer position and the prober door 550 is opened to facilitate prober transfer. The support members 310A, 310B are suitably joined to an actuator shaft 723 so that any vertical movement imparted by the support member actuator 320 is shared by the support members 310A, 310B. The support member 310B is shown in a vertical position to transfer a prober 205 (not shown) to the prober lift member 626 or receive a prober from the prober lift member 626. The lift member 626 of the prober positioning assembly 625 is shown raised by the actuator shaft 723 coupled to the Z-motor 620 (not shown in this view). The raised position of the prober lift member 626 puts the lift member and the support member 310B in substantially the same horizontal plane and prober transfer may occur across this horizontal plane.

In one embodiment, the prober lift members 626 may be moved by the testing table 535 in an X direction to within about two inches of the lower support member 310B, thereby providing a transfer path for the prober 205 that is aligned in the same horizontal plane with a small gap therebetween. The gap may be of a size that is negligible to transfer and the prober 205 may be transferred across the prober lift members 626 laterally out of the testing chamber and onto the lower support member 310B of the prober exchanger 300. In another embodiment, the prober lift members 626 may be moved by the testing table 535, to provide a transfer path for the prober 205 with little or no gap. In yet another embodiment, the prober exchanger 300 may be adapted to move the support members 310A, 310B in an X direction to provide a transfer path for the prober 205 with little or no gap. Regardless of any X directional movement of the testing table 535 or the prober exchanger 300, the prober lift members 626 are aligned in the same horizontal and vertical plane with the lower support member 310B by horizontal movement of the testing table 535 and vertical movement of the prober exchanger 300. Once positioned in substantially horizontal plane, the prober may be transferred from the lower support member 310B to the prober lift member 626 by horizontal movement along this plane.

The support members 310A, 310B in this embodiment include a plurality of rollers 761 and 762. The bottom rollers 761 support the prober frame 510 similar to the lower rollers 760 of the prober lift member 626, and the side rollers 762 act as a guide for the prober frame 510 similar to the upper rollers 750 of the prober lift member 626.

In operation, a large area substrate 101 may be supported by the fingers of the end effector 570 as the prober lift member 626 is in an upper position. The substrate 101 may be transferred out of the testing chamber 500 and another substrate may be transferred into the chamber. The prober transfer step may occur at any point during this transfer when the prober transfer position and the substrate transfer position of the testing table 535 are the same. Alternatively, the substrate transfer position and the prober transfer position of the testing table 535 may be different and each of the prober transfer and substrate transfer may be executed at different times.

Once a to-be-tested substrate is transferred to the testing table 535 and is in position above the testing table, the Z-stage 536 may be raised vertically to support the substrate by a plurality of stage actuators 775 coupled to the upper stage 555. When the appropriate prober is transferred to the testing chamber and is supported by the prober lift member 626, the prober lift member may be actuated downward to place the prober frame in contact with the prober support 630. As shown, the prober support 630 is coupled to an upper surface of the upper stage 555. Once the prober is coupled to the prober support 630, the Z-stage 536, with a large area substrate thereon, may be raised to contact the prober and a testing sequence may commence.

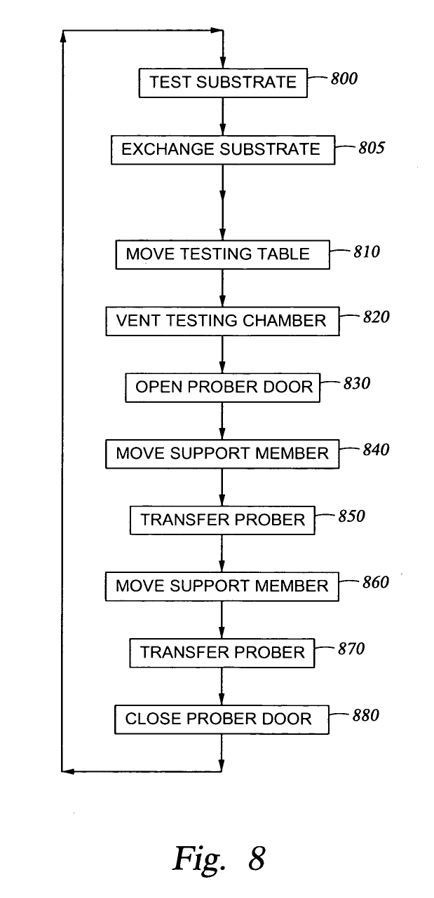

FIG. 8 is a flow chart showing steps of an exemplary operation. Step 800 begins with a testing sequence performed on a first substrate, which may comprise a plurality of 17 inch flat panel displays. When the first substrate is tested, a second substrate, which may comprise a plurality of 46 inch flat panel displays, may be next in the load lock chamber 400 for testing. The first substrate may have a different conductive contact area layout than the conductive contact area layout of the second substrate, and a second prober may be employed to test the second substrate. In this case, a substrate transfer step, to transfer the first substrate and second substrate, and a prober transfer step, to transfer the first and second probers, must occur.

Although the method described in FIG. 8 has a substrate transfer step 805 following the test substrate step 800, the method is not limited to this description and the exchange substrate step 805, or substrate transfer step, may be executed at any point in the method except during testing. The method will be further described based on alternative embodiments dependent on the substrate transfer position and the prober transfer position of the substrate table 535 in the testing chamber 500.

If the prober transfer position and the substrate transfer positions of the substrate table 535 are different, step 805 may be executed. The Z-stage 536 may be actuated downward in a Z direction to put the first substrate and the first prober in a spaced apart relation, thereby discontinuing contact between the conductive contact areas of first substrate and the contact pins 512 of the first prober. The Z-stage may continue in a downward Z direction to allow the fingers of the end effector 570 to support the first substrate as shown in FIG. 7B. The end effector 570 transfers the first substrate to the load lock chamber 400 and transfers the second substrate to the testing chamber 500 and the Z-stage 536 is actuated downward to place the second substrate on the upper surface of the Z-stage 536, thus completing the substrate transfer step 805.

The substrate table 535 may then be moved (Step 810) to a prober transfer position within the testing chamber 500 and the testing chamber vented down (Step 820) to allow the prober door to be opened (Step 830). Step 840 includes moving the support members 310A, 310B of the prober exchanger 300 to a vertical position that defines a prober transfer position. More particularly, the upper support member 310A of the prober exchanger 300 may have been preloaded with the second prober while the lower support member 310B has been left vacant to receive the first prober. In this case, the lower support member 310B will be positioned vertically outside the testing chamber 500 to facilitate transfer of the first prober, as shown in FIG. 7B. Alternatively, step 840 may previously be executed and the support member 310B may already be in a prober transfer position before the prober door is opened.

Step 850 may be executed which includes transferring the first prober from the testing chamber to the vacant support member of the prober exchanger 300 that is aligned with the prober lift member 626 of the prober positioning assembly, which in this case is the lower support member 310B. The prober lift member 626 and the lower support member are in the same horizontal and vertical position which allows the first prober to be transferred out of the testing chamber 500 laterally onto the lower support member 310B. Step 860 includes moving the support members 310A and 310B of the prober exchanger 300 relative the exchanger frame to position the support member having the second prober thereon to a transfer position, which in this case is the upper support member 310A. The prober lift member 626 may remain in the same vertical and horizontal position to allow the upper support member 310A to be positioned in the same horizontal and vertical position relative the prober lift member 626, which allows the second prober to be transferred out of the upper support member 310A laterally into the testing chamber 500 to complete step 870. The second prober may be limited in this lateral movement by a stop 725 (FIG. 7A) coupled to the prober lift member 626.

Step 880 includes closing the prober door and pumping down the testing chamber 500 for a testing sequence. The second prober, now supported by the prober positioning assembly 625, may be actuated downward in a Z direction to cause the second prober to contact the prober support 630 coupled to the testing table 535. The Z-stage 536, having the second substrate thereon, may be actuated upward to bring the second substrate into contact with the second prober. Specifically, the conductive contact areas of the second substrate are brought into contact with the contact pins 512 of the second prober. Once the prober door is closed, sealing the testing chamber 500 and allowing a vacuum to be provided in the interior of the chamber, the method goes to step 800 wherein the second substrate is tested.

If the conductive contact area layout of a third substrate is different than the conductive contact area layout of the second substrate, the method returns to step 810 after the substrate transfer step 805 to transfer the second prober out of the testing chamber and transfer a third prober into the chamber. If the conductive contact area layout of the third substrate is the same as the second substrate, the substrate transfer step 805 may be executed which includes transferring the second substrate out of the testing chamber and transferring the third substrate into the testing chamber to be tested using the second prober.

Alternatively, if the prober transfer position and the substrate transfer position is the same and the testing sequence is complete on the first substrate, the prober lift members 626 may be actuated in an upward Z direction to place the first substrate and the first prober in a spaced apart relation while aligning the prober lift members 626 of the prober positioning assembly 625 to a prober transfer position to facilitate transfer of the first prober. The first substrate may be supported by the fingers of the end effector 570 and transferred into the load lock chamber 400 and the end effector 570 may retrieve the second substrate from the load lock chamber 400 and transfer the second substrate to the testing chamber. Since the prober lift members 626 are in a position above the substrate table 535 that provides no interference with any of the substrate transfer sequence, all of the method steps 820-880 as described above may be performed during the substrate transfer sequence. Once step 880 has been performed, the testing sequence may begin on the second substrate.

FIG. 9 is another embodiment of an electron beam test system 100 having a testing chamber 800 that also functions as a load lock chamber. In this embodiment, the testing chamber 800 is selectively sealed from ambient environment by slit valves 810A, 810B, and is coupled to one pressure system designed to provide negative pressure to the interior of the testing chamber 800. Each of the slit valves 810A, 810B have one actuator 820 to open and close the slit valves when needed. A prober exchanger 300 is positioned adjacent the testing chamber 800 and facilitates transfer of one or more probers into and out of the testing chamber 800. Other exemplary systems in which the embodiments of a prober exchanger can be used to advantage include U.S. Provisional Patent Application No. 60/676,558 (Attorney Docket No. AMAT/0010191L), entitled “In-Line Electron Beam Test System,” filed Apr. 29, 2005, which is incorporated herein by reference to the extent not inconsistent with this application.

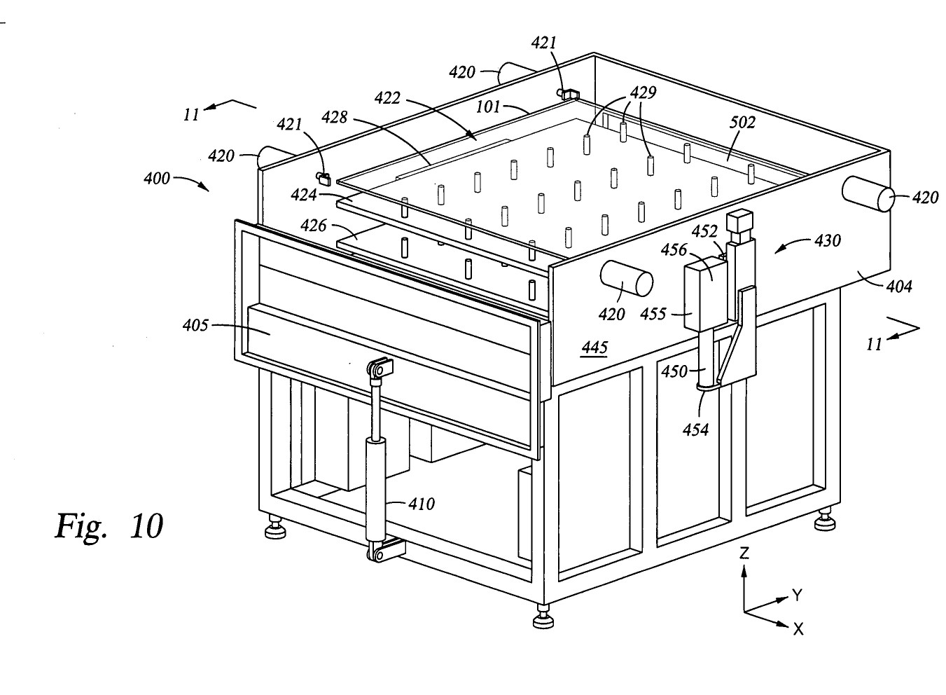

FIG. 10 is an isometric view of the load lock chamber 400 of FIG. 1. The load lock chamber 400 includes a dual slot substrate support 422 having an upper support tray 424 and a lower support tray 426 coupled to spacer blocks 428 on opposing sides of the dual slot substrate support 422 (only one spacer block is seen in this view). Each of the support trays 424, 426 have a plurality of support pins 429 coupled to the support trays which are configured to support a substrate on each of the support trays 424, 426. Each of the support trays 424, 426 are coupled to and spaced apart by the spacer block 428. A transfer door 405 is adapted to selectively open and close to ambient environment by a door actuator 410. The transfer door 405 may be adjacent an atmospheric substrate queuing system and is adapted to transfer substrates into and out of the load lock chamber to and from ambient environment. The load lock chamber is coupled to the testing chamber (not shown) by a slit valve 502. An exemplary load lock chamber having a dual slot substrate support in which embodiments of the load lock chamber 400 can be used to advantage is described in the description of FIGS. 3, 4, and 17-20 of U.S. Pat. No. 6,833,717, entitled “Electron Beam Test System with Integrated Substrate Transfer Module,” which issued Dec. 21, 2004, which was previously incorporated by reference.

The load lock chamber 400 includes at least one lift actuator 430 that provides at least vertical movement and support to the dual slot substrate support 422. In this embodiment, the load lock chamber 400 includes two lift actuators 430 coupled to the body 404. Each of the lift actuators 430 include a lift motor 452, a base 454 coupled to the lift motor 452 by a shaft 450 coupled to the base 454. A housing 455 is also coupled to the body 404 and is sealed by a cover 456. The load lock chamber 400 also has a plurality of substrate aligners 420 disposed through the chamber body 404 adjacent the corners of the dual slot substrate support 422. The substrate aligners 420 are configured to correct the alignment of the substrate before the substrate is transferred into the testing chamber or after the substrate has been transferred out of the testing chamber. Each of the substrate aligners 420 have an alignment member 421 coupled to a shaft disposed through the body 404. The alignment members 421 are made of a polymer or plastic material that is adapted for use in a vacuum environment and resists abrasion, such as a PEEK material. In one embodiment, the alignment members 421 are configured to selectively nudge and/or provide a stop for the corners and/or sides of the large area substrate 101. The alignment members 421 may include at least one rolling member, such as a wheel made of a plastic material, that is designed to push the large area substrate without damaging the large area substrate. In another embodiment, at least one of the alignment members 421 may be a reference member, such as a roller made of plastic, and at least one other alignment member may be another wheel made of plastic configured to push the large area substrate at a corner or side to a position that brings the large area substrate into proper alignment, based on substrate position relative to the reference member. In another embodiment, each of the alignment members 421 may include two rolling members made of plastic, wherein one of the rolling members acts as a reference member, and the other is configured to push the large area substrate, if needed, to adjust the alignment of the large area substrate based on substrate position relative to the reference member. The pushing action of the alignment member may be provided by a mechanical actuator, a pneumatic actuator, a hydraulic actuator, a biasing member, such as a spring, or combinations thereof. The substrate aligners 420 are coupled to the chamber body 404 to maintain a vacuum seal and any parts that extend into the interior of the load lock chamber 400 are effectively sealed from ambient environment by appropriate seals.

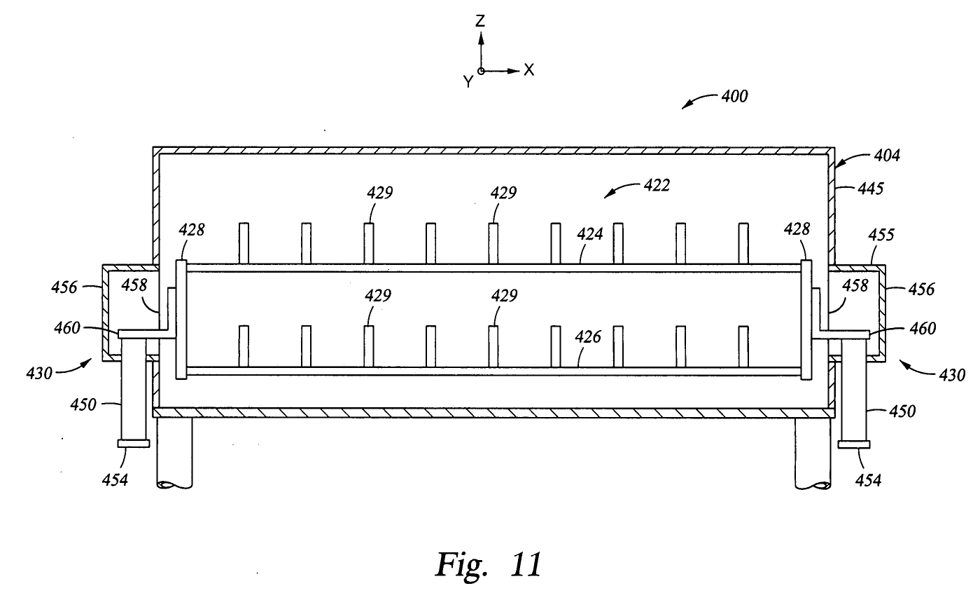

FIG. 11 is a schematic side view of a portion of the load lock chamber 400 showing the coupling of the lift actuators 430 to the dual slot substrate support 422. The body 404 of the load lock chamber 400 has a top, a bottom, and a sidewall 445. Each of the lift actuators 430 have a brace 460 that is coupled to the shaft 450. Each brace 460 extends through an opening 458 in a sidewall 445 of the body 404 and is coupled to the spacer blocks 428 on opposing sides of the dual slot substrate support 422. Each shaft 450 is movably disposed through a suitable bore in the lower surface of the housing 455 and, in one embodiment, a vacuum tight seal is provided around the shaft 450 by the use of o-rings or vacuum tight covers (not shown). In another embodiment, a vacuum tight seal is created by a flexible bellow (not shown) covering the shaft 450. The bellow is coupled and sealed on one end to the base 454 and coupled and sealed on the other end to the brace 460 and is adapted to expand and contract while holding vacuum.

The housing 455 permits vertical movement for the brace 460 and is coupled to the sidewall 455 in a manner that provides a vacuum tight seal for the opening 458, such as by bolts or screws and gaskets, or joining by welding. The cover 456 may be removable to permit access to certain parts of the load lock chamber 400 if needed, and is sealed by screws or bolts and gaskets to the housing 455 in order to maintain vacuum within the load lock chamber 400. In one embodiment, the cover 456 is transparent and made of polymeric materials to allow an operator to inspect a portion of the load lock chamber 400 visually. In another embodiment, the cover 456 is not transparent and is made of a process resistant material, such as a polymer or a metal and may further be coupled to the housing 455 to form an integral wall.

In operation, a large area substrate is transferred to the load lock chamber 400 from an atmospheric queuing system through the transfer door 405. The large area substrate may be placed on the upper support tray 424 while the lower support tray 426 may be left vacant to receive a tested substrate from the testing chamber, or vice versa. Alternatively or additionally, the atmospheric queuing system may unload a previously tested substrate from the load lock chamber 400 while loading a to-be-tested substrate into the load lock chamber 400. Once the to-be-tested substrate is supported by one of the support trays 424, 426 and the atmospheric queuing system has exited the load lock chamber 400, the transfer door 405 may be closed.

The fingers of the end effector 570 (FIG. 6) are adapted to extend into the load lock chamber 400 through the slit valve 502 to transfer the to-be-tested substrate into the testing chamber. Prior to transfer into the testing chamber, the substrate may be in need of alignment. This alignment may be accomplished by alignment members 421 coupled to the plurality of substrate aligners 420. The alignment members 421 are adapted to contact a portion of the substrate and urge the substrate to a desired position on the respective support tray 424, 426. The substrate aligners 420 are actuated by suitable drives that may move the substrate in very small increments in the X or Y direction to correct any misalignment in the substrate. The substrate aligners 420 and the respective alignment members 421 are adapted to be stationary in the Z direction, using the atmospheric lift actuators 430 to position the dual slot substrate support 422 vertically. The vertical movement of the dual slot substrate support 422, having a substrate thereon, positions the substrate for aligning and interaction with the end effector 570 for transfer.

While the foregoing is directed to embodiments of the present invention, other and further embodiments of the invention may be devised without departing from the basic scope thereof, and the scope thereof is determined by the claims that follow.

1. A test system for testing at least one large area substrate, comprising:
a testing chamber coupled to a load lock chamber configured to facilitate transfer of the large area substrate, the testing chamber having a movable testing table within an interior volume; and
a positioning assembly coupled to the testing table, wherein the positioning assembly is movable relative the testing table and is configured to transfer one or more probers into and out of the testing chamber, wherein the positioning assembly is adapted to transfer the one or more probers to and from a prober exchanger positioned adjacent the chamber.

2. The system of claim 1, wherein the prober exchanger further comprises:
a frame; and
at least one actuator coupled to the frame.

3. The system of claim 2, wherein the prober exchanger comprises one or more support members coupled to the at least one actuator, the support members adapted to receive the one or more probers.

4. The system of claim 3, wherein the one or more support members are adapted to move relative the positioning assembly.

5. The system of claim 4, wherein the one or more support members are adapted to move relative the frame.

6. The system of claim 1, wherein the load lock chamber has a plurality of alignment members adapted to alter the orientation of the large area substrate.

7. The system of claim 1, wherein the positioning assembly further comprises:
two lift members having a plurality of friction reducing members adapted to movably support one of the one or more probers; and
at least two drives adapted to raise and lower the lift members.

8. The system of claim 1, further comprising:
a plurality of electron beam columns coupled to an upper surface of the chamber.

9. An apparatus for transferring one or more probers into and out of a testing chamber, comprising:
at least two lift members, each lift member having a plurality of rollers;
at least one drive coupled to the lift member; and
a plurality of support members positioned adjacent the testing chamber, the plurality of support members configured to transfer the probers to and from the lift member.

10. The apparatus of claim 9, wherein the at least one drive is coupled to a substrate support within the chamber and is adapted to move the lift member relative the substrate support.

11. The apparatus of claim 9, wherein the lift member is adapted to transfer and movably support one of the one or more probers.

12. The apparatus of claim 9, wherein the plurality of support members further comprise:
a friction reducing surface; and
a frame configured to support the plurality of support members, wherein the plurality of support members are coupled to at least one drive configured to move the support members relative to the frame.

13. The apparatus of claim 12, wherein the frame is coupled to a testing chamber configured to test electronic devices on large area substrates.

14. The apparatus of claim 13, wherein the testing chamber is coupled to a load lock chamber configured to support and facilitate transfer of one or more large area substrates.

15. The apparatus of claim 14, wherein the load lock chamber further comprises:
a plurality of support trays configured to support and facilitate transfer of at least two substrates;
a lift system coupled to the plurality of support trays; and
a plurality of substrate alignment devices configured to correct misalignment of at least one of the substrates.

16. The apparatus of claim 14, wherein the load lock chamber further comprises:
a transfer door configured to facilitate transfer of the one or more substrates into and out of ambient environment; and
an actuator coupled to the transfer door to move the transfer door from an open position to a closed position.

17. A method for transferring one or more probers into and out of a testing chamber, comprising:
moving a support member adjacent the testing chamber vertically to a first vertical position;
moving a testing table within the chamber into horizontal alignment with the support member in the first vertical position; and
transferring a prober from the support member to a transfer assembly coupled to the testing table laterally across the support member to the transfer assembly.

18. The method of claim 17, further comprising:
moving the transfer assembly coupled to the testing table to substantially match the first vertical position of the support member before transferring the prober.

19. The method of claim 17, further comprising:
moving the support member vertically to a second vertical position; and
transferring the prober from the transfer assembly to the support member laterally across the transfer assembly to the support member.

20. A load lock chamber for transferring one or more large area substrates, comprising:
a body having a top, a bottom, and a sidewall;
a substrate support within the body; and
at least two actuators coupled to the substrate support through the sidewall.

21. The load lock chamber of claim 20, wherein the substrate support further comprises:
at least two support trays spaced apart and coupled by at least two spacer blocks on opposing sides of the at least two support trays.

22. The load lock chamber of claim 21, wherein the each of the at least two support trays include a plurality of support pins configured to support one of the one or more large area substrates.

23. The load lock chamber of claim 21, wherein the at least two actuators are coupled to the at least two spacer blocks.

24. The load lock chamber of claim 20, further comprising:
a plurality of substrate aligners coupled to the body.

25. The load lock chamber of claim 24, wherein each of the plurality of substrate aligners include an alignment member adapted to reorient one of the large area substrates.
